(19) United States
(12) Patent Application Publication
(10) Pub. No.: US 2025/0113474 A1
(43) Pub. Date: Apr. 3, 2025

(54) Electrostatic Shield For Electronic Device

(71) Applicant: APPLE INC., Cupertino, CA (US)

(72) Inventors: Shaowu Huang, Los Altos, CA (US); Keong W. Kam, San Jose, CA (US); Ramachandran Chundru, Cupertino, CA (US); Jing Li Lim, Sunnyvale, CA (US); Martin R. Kardasz, Mountain View, CA (US); Jan K. Quijalvo, San Jose, CA (US); Michael J. Woods, Sunnyvale, CA (US)

(21) Appl. No.: 18/806,239

(22) Filed: Aug. 15, 2024

Related U.S. Application Data
(60) Provisional application No. 63/540,953, filed on Sep. 28, 2023.

(51) Int. Cl. H05K 9/00; G06F 1/16

(52) U.S. Cl. CPC H05K 9/0054; G06F 1/163

(57) ABSTRACT

A head-mounted device includes a frame and a stage movably coupled to the frame. The head-mounted device includes an optical module that is configured to show content, is coupled to the stage, and is configured to move laterally relative to the frame. An optical module control board is configured to provide the content to the optical module and has a surface that includes exposed electrical connections positioned around a perimeter of the surface. The head-mounted device also includes a shield assembly that has a first shield portion and a second shield portion. The first shield portion is configured to cover the surface of the optical module control board, to extend partially around the perimeter of the surface to cover the exposed electrical connections, and to dissipate an electrical charge. The second shield portion is configured to cover a flexible electrical connector.

### CROSS-REFERENCE TO RELATED APPLICATIONS

This application claims priority to U.S. Provisional Application Ser. No. 63/540,953, filed Sep. 28, 2023, the contents of which are incorporated herein by reference.

### FIELD

The present disclosure relates generally to the field of protecting an electronic device from the effects of electrostatic discharge and electrostatic coupling.

### BACKGROUND

A head-mounted device may include various electronic components configured for operation of the head-mounted device and to display content. Operation of the electronic components may be negatively affected if exposed to an electrostatic discharge or electrostatic coupling.

### SUMMARY

One aspect of the disclosure is a head-mounted device that includes a frame and a stage movably coupled to the frame. The head-mounted device includes an optical module that is configured to show content, is coupled to the stage, and is configured to move laterally relative to the frame. An optical module control board is configured to provide the content to the optical module and has a surface that includes exposed electrical connections positioned around a perimeter of the surface. A flexible electrical connector is electrically coupled to the optical module and to the optical module control board. The head-mounted device also includes a shield assembly that has a first shield portion and a second shield portion. The first shield portion is configured to cover the surface of the optical module control board, to extend partially around the perimeter of the surface to cover the exposed electrical connections, and to dissipate an electrical charge. The second shield portion is configured to cover the flexible electrical connector to dissipate the electrical charge.

Another aspect of the disclosure is a head-mounted device that includes a frame and an optical module coupled to the frame that is configured to show content. An optical module control board is configured to provide the content to the optical module and has a first surface and a second surface. The first surface has exposed electrical connections positioned around a perimeter of the first surface, and the second surface is located opposite the first surface. An edge extends between the first surface and the second surface. A deformable shield is configured to cover the optical module control board and includes a first shield portion, a second shield portion, and a third shield portion. The first shield portion is configured to cover the first surface to direct an electrical charge away from the first surface. The second shield portion is configured to cover the second surface to direct the electrical charge away from the second surface. The third shield portion is configured to cover the edge to direct the electrical charge away from the edge.

Yet another aspect of the disclosure is a head-mounted device that includes a frame and an optical module movable relative to the frame and configured to show content. An optical module control board is configured to provide the content to the optical module and has a first surface and a second surface. The first surface includes exposed electrical connections positioned around a perimeter of the first surface, and the second surface is located opposite the first surface. An edge extends between the first surface and the second surface. A shield assembly includes a first shield portion and a second shield portion. The first shield portion has a first shield outer section configured to cover the first surface and a first shield edge section configured to cover a first portion of the edge. The first shield outer section and the first shield edge section are oriented along different planes. The second shield portion has a second shield outer section configured to cover the second surface and a second shield edge section configured to cover a second portion of the edge. The second shield outer section and the second shield edge section are oriented along different planes.

### BRIEF DESCRIPTION OF THE DRAWINGS

FIG. 1 is an illustration of a head-mounted device.

FIG. 2 is an illustration of an optical module of the head-mounted device of FIG. 1.

FIGS. 3A-3B are illustrations of a shield assembly.

FIGS. 4A-4B are illustrations of a shield assembly.

FIGS. 5A-5B are illustrations of a deformable shield.

FIGS. 6A-6C are illustrations of a shield assembly.

### DETAILED DESCRIPTION

The disclosure herein relates to a head-mounted device with an optical module that has a display for showing content to a user. The optical module may also have an optical module control board electrically coupled to the optical module that may be configured to provide the content to the display. In some instances, the head-mounted device may be susceptible to the effects of an electrostatic charge that accumulates on components of the head-mounted device, such as an electrostatic discharge or electrostatic coupling. Operation of the head-mounted device may be affected when the electronic components within the head-mounted device (e.g., the optical module control board, electrical connectors, etc.) are exposed to the electrostatic discharge or electrostatic coupling.

Implementations herein are directed to a head-mounted device including a shield assembly configured to cover a portion of an optical module control board associated with an optical module of the head-mounted device. The shield assembly may be configured to dissipate and/or redirect an electrical charge associated with an electrostatic discharge or electrostatic coupling directed toward the optical module control board, thereby limiting damage to the optical module control board that would otherwise occur if the electrical charge were not dissipated and/or redirected. The head-mounted device may also include a flexible connector to electrically couple the optical module control board with the optical module. In some implementations, the shield assembly is also configured to dissipate and/or redirect an electrical charge directed toward the flexible connector, thereby limiting damage to the flexible connector that would otherwise occur if the electrical charge were not dissipated and/or redirected.

In some implementations, the shield assembly includes various shield components that are configured to cover respective portions of the optical module control board. The shield components may be adhesively coupled to the optical module control board and may directly contact one or more surfaces of the optical module control board. The shield components may also be adhesively coupled to the flexible connector. In some implementations, the shield components may be flexible.

In some implementations, the shield assembly includes a deformable shield configured to cover various surfaces of the optical module control board. The deformable shield may be a continuous structure configured to limit gaps between different portions of the deformable shield as the deformable shield extends around the various surfaces of the optical module control board.

The shield assembly may include a first shield portion and a second shield portion. The first shield portion may be configured to cover a first surface of the optical module control board and a first portion of an edge of the optical module control board. The second shield portion may be configured to cover a second surface of the optical module control board and a second portion of the edge of the optical module control board. The first shield portion may be configured to overlap the second shield portion along the edge of the optical module control board.

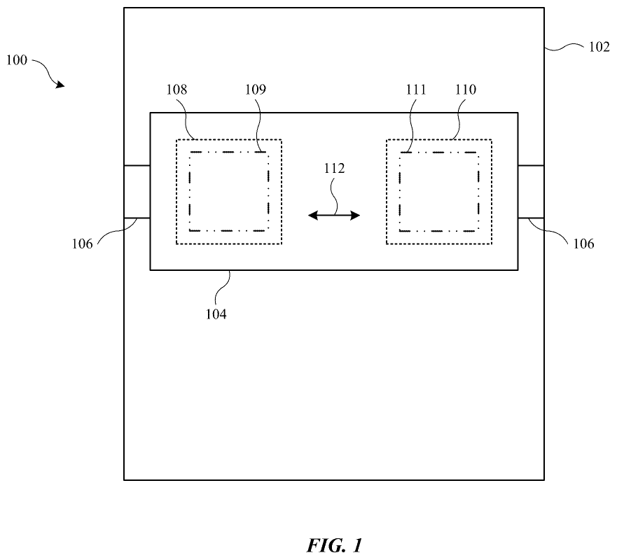

FIG. 1 is an illustration of a head-mounted device 100 worn by a user. The head-mounted device 100 is a computer-generated reality device that is configured to display computer-generated reality content to the user 102 using a near-eye display, and optionally according to tracked motion of the head-mounted device 100 in order to display computer-generated reality content to the user 102 in a manner that simulates viewing of the content based on the position and orientation of the head of the user 102. As one example, the head-mounted device 100 may be configured as a virtual reality device in which the head-mounted device 100 blocks images from the environment from reaching the user 102 and instead presents the user 102 with virtual images presented on a display near the eyes of the user 102. As another example, the head-mounted device 100 may be configured as a video passthrough augmented reality device in which the head-mounted device 100 obtains images of the environment around the head-mounted device 100 (e.g., using one or more cameras), superimposes virtual images on top of the images from the environment in order to define combined images, and displays the combined images to the user 102 via one or more displays (e.g., including one or more display screens and lenses). Other configurations may be used for the head-mounted device 100.

The head-mounted device 100 includes a frame 104 that is configured to provide structural support for components of the head-mounted device 100 that are coupled directly or indirectly to the frame 104. The frame 104 may be formed from any type of material of sufficient strength to support the components of the head-mounted device 100. For example, the frame 104 may be formed from metal (e.g., aluminum, zinc, nickel, brass, steel, etc., or a combination thereof). The frame 104 may also be formed from plastic (e.g., polycarbonate, polypropylene, nylon, etc., or a combination thereof). In some implementations, the frame 104 may include multiple parts (e.g., the frame 104 may be a multi-part assembly), and the parts may be formed from the same material or different materials. In some implementations, the frame 104 of the head-mounted device 100 is formed, at least in part, from a conductive material having sufficient mass to allow the frame 104 to serve as a ground for components of the head-mounted device 100.

The head-mounted device 100 may include a headband 106 configured to secure the head-mounted device 100 to the head of the user 102. As shown, the headband 106 is coupled to the frame 104 and may extend around a back of the head of the user 102. The headband 106 may be formed from any material capable of securing the head-mounted device 100 to the head of the user 102. For example, the headband 106 may be formed from a stretchable material (e.g., an elastic textile material) configured to expand to accommodate the head of the user 102 and to contract around the head of the user 102 to secure the head-mounted device 100 to the head of the user 102.

The head-mounted device 100 may include a first optical module 108 and a second optical module 110. The first optical module 108 may be configured to show content to a first eye of the user 102 via a first display 109. The second optical module 110 may be configured to show the content to a second eye of the user 102 via a second display 111. Each of the first display 109 and the second display 111 may be a light-emitted display component, such as a display screen, that is configured to show content to the user 102 that is wearing the head-mounted device 100. In some implementations, each of the first display 109 and the second display 111 may be a liquid crystal display. Each of the first display 109 and the second display 111 may also be an organic light emitting diode (OLED) display. In some implementations, each of the first display 109 and the second display 111 may be a digital light projector (DLP) microdisplay. Each of the first display 109 and the second display 111 may also be a liquid crystal on silicon (LCoS) microdisplay. The above are examples of implementations of the first display 109 and the second display 111, and other systems or devices for displaying content to the user 102 may also be implemented.

In some implementations, the first optical module 108 and the second optical module 110 are movably coupled to the frame 104. For example, the first optical module 108 and the second optical module 110 may be movable in a lateral direction (e.g., in the direction of the arrow 112) relative to the frame 104. The first optical module 108 and the second optical module 110 may also be movable in the lateral direction relative to each other. Allowing lateral movement between the first optical module 108 and the second optical module 110 allows the user 102 to adjust a distance between the first optical module 108 and the second optical module 110 to accommodate an interpupillary distance between the eyes of the user 102.

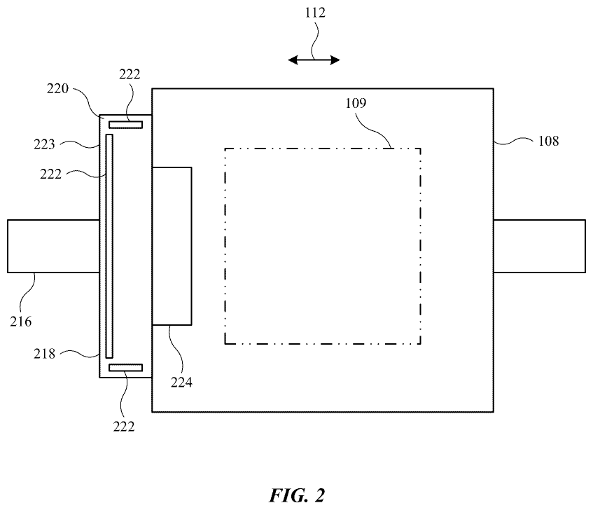

FIG. 2 is an illustration of the first optical module 108 of the head-mounted device 100 of FIG. 1. Though the description below refers to the first optical module 108, the description also applies to the second optical module 110. The first optical module 108 may be configured to show content to the user 102 and may include various components that facilitate providing the content to the user 102. For example, the first optical module 108 is shown to include the first display 109 (e.g., a screen) configured to show the content. The first optical module 108 may also include a lens configured to direct images of the content to an eye of the user 102.

The first optical module 108 may be coupled to a stage 216. The stage 216 may be configured to move the first optical module 108 relative to the frame 104 and/or the second optical module 110 in the direction of the arrow 112 (e.g., the lateral direction). In some implementations, the first optical module 108 is fixed to the stage 216 and the stage 216 is movably coupled to the frame 104. More specifically, the stage 216 may be supported with respect to the frame 104 in a manner that allows movement, such as by sliding along rods or tracks, and the stage 216 may be coupled to an actuator (e.g., an electric linear actuator such as a lead screw rotated by an electric motor) configured to move the stage 216 laterally relative to the frame 104. Accordingly, the first optical module 108 may be configured to move laterally relative to the frame 104 based on lateral movement of the stage 216 relative to the frame 104. The first optical module 108 may also be movably coupled to the stage 216, and the stage 216 may be fixed to the frame 104. For example, the stage 216 may include an actuator (e.g., an electric linear actuator) configured to move the first optical module 108 relative to the stage 216. Thus, the first optical module 108 may be configured to move laterally relative to the frame 104 based on lateral movement of the first optical module 108 relative to the stage 216.

The first optical module 108 is coupled to an optical module control board 218 via a flexible electrical connector 224. The optical module control board 218 may be configured to provide the content to the first optical module 108. For example, the optical module control board 218 may be coupled to a main control board configured to provide a content signal (e.g., a video signal including a series of images) to the optical module control board 218. Based on the content signal, the optical module control board 218 may be configured to provide the content to the first optical module 108 to show the content to the user 102 (e.g., via the first display 109).

The optical module control board 218 has a first surface 220 that includes exposed electrical connections 222 positioned around a perimeter 223 of the first surface 220. In some implementations, the electrical connections 222 may be electrical pins that may serve as input or output pins for circuits located on the optical module control board 218. Though the exposed electrical connections 222 are shown as extending around three sides of the optical module control board 218, the exposed electrical connections 222 may extend around any portion of the first surface 220 of the optical module control board 218. For example, the exposed electrical connections 222 may extend around one side, two sides, four sides, etc., of the optical module control board 218. Additionally, the optical module control board 218 is shown as having a rectangular shape, however the optical module control board 218 may have any geometric or non-geometric shape suitable for operation of the optical module control board 218. For example, the optical module control board 218 may have more than four sides or fewer than four sides. In some implementations, the optical module control board 218 may have a round shape (e.g., a circle, ellipse, etc.). In any implementation, the exposed electrical connections 222 are configured to extend either partially or fully around the perimeter 223 of the first surface 220 of the optical module control board 218.

The flexible electrical connector 224 is electrically coupled to the first optical module 108 and to the optical module control board 218. The flexible electrical connector 224 may be configured to provide a signal generated by the optical module control board 218 to the first display 109. For example, the optical module control board 218 may be configured to provide a signal for the content to be shown to the user 102 to the first optical module 108 via the flexible electrical connector 224. The flexible electrical connector 224 may provide the signal to the first display 109 to show the content to the user 102. In some implementations, the flexible electrical connector 224 may be a flexible flat cable, a flexible printed circuit, a flexible ribbon cable, or any other type of electrical connector suitable to facilitate a flexible connection between the optical module control board 218 and the first display 109.

In some implementations, the optical module control board 218 and/or the flexible electrical connector 224 may be susceptible to an electrostatic discharge or electrostatic coupling from an electrically charged object in proximity to the head-mounted device 100. In some implementations, the charged object may be another electronic device. The charged object may also be a non-electronic device that has accumulated static electricity. The charged object may be a portion of the head-mounted device 100 that has accumulated static electricity. For example, the charged object may be the user 102 (e.g., the user 102 may accumulate an electrical charge by, for example, walking across a carpeted floor, and the accumulated electrical charge may flow to the head-mounted device 100 when the user 102 attempts to touch the head-mounted device 100). The charged object may also be another user that is not wearing the head-mounted device 100.

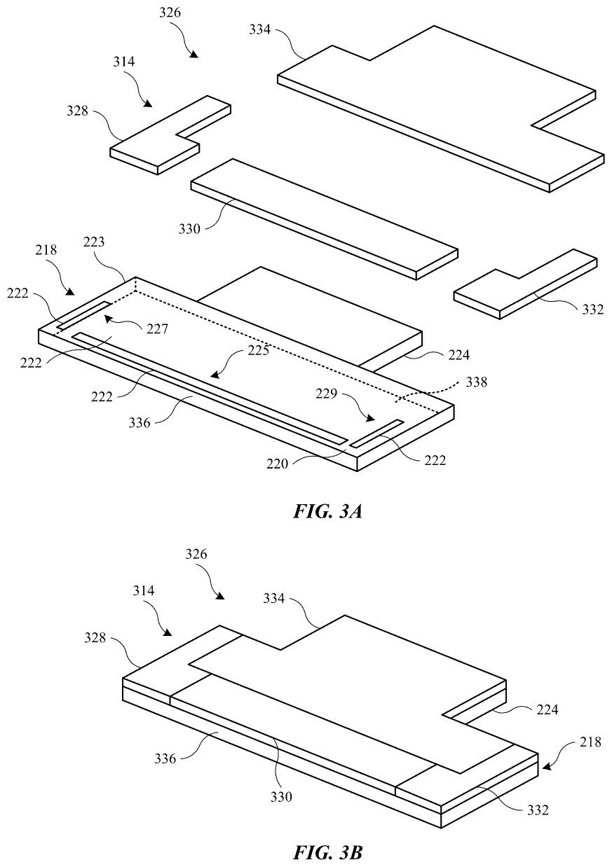

The electrical charge may also be in the form of electrostatic coupling between the head-mounted device 100 and an electrically charged object in proximity to the head-mounted device 100. For example, electrical energy from an electric field associated with the optical module control board 228 and/or the flexible electrical connector 224 may couple with electrical energy from an electric field associated with the electrically charged object, thereby increasing the electrical energy in the optical module control board 228 and/or the flexible electrical connector 224. Increasing the electrical energy in the optical module control board 228 and/or the flexible electrical connector 224 may limit performance of the optical module control board 228 and/or the flexible electrical connector 224. When subjected to an electrical charge from electrostatic discharge or electrostatic coupling of a nearby object, operation of the optical module control board 218 and/or the flexible electrical connector 224 may be impacted. To limit exposure of the optical module control board 218 and the flexible electrical connector 224 to an electrical charge, a shield may be used to dissipate and/or redirect the electrical charge. The shield may also prevent accumulation of an electrical charge on portions of the head-mounted device 100 that are located near the shield. Examples of implementations of various shields that may be used are described in FIGS. 3A-6B.

FIGS. 3A-3B are illustrations of a shield assembly 326. FIG. 3A is an illustration of an exploded view of the shield assembly 326 in a disassembled configuration. FIG. 3B is an illustration of the shield assembly 326 in an assembled configuration and coupled to the optical module control board 218 and the flexible electrical connector 224 of FIG. 2.

The shield assembly 326 may be configured to cover a portion of the optical module control board 218 and/or the flexible electrical connector 224 to dissipate and/or redirect an electrical charge (e.g., from an electrostatic discharge or electrostatic coupling). For example, the shield assembly 326 may be physically coupled to the optical module control board 218 such that at least a portion of the shield assembly 326 is spaced from the first surface 220, and such that the electrical connections 222 are located between the first surface 220 and the shield assembly 326. The optical module control board 218 is shown to include a second surface 338 (in dotted line) located opposite the first surface 220. An edge 336 extends between the first surface 220 and the second surface 338.

The shield assembly 326 is shown to include a first shield portion 314. The first shield portion 314 may be configured to cover the first surface 220 to cover the exposed electrical connections 222 (e.g., as shown in FIG. 3B). Thus, the first shield portion 314 may be configured to extend around the perimeter 223 of the first surface 220 to cover the exposed electrical connections 222 and to dissipate and/or redirect the electrical charge. More specifically, the first shield portion 314 may be configured to extend at least partially around the perimeter 223 of the first surface 220 to cover the exposed electrical connections 222. For example, the exposed electrical connections 222 may extend around three sides of the first surface 220 as shown in FIG. 3A. Therefore, the first shield portion 314 may extend around the three sides of the first surface 220 that include the exposed electrical connections 222. In implementations where the exposed electrical connections 222 extend around more or fewer sides, the first shield portion 314 may be configured to extend around the same number of sides of the first surface 220 as include the exposed electrical connections 222.

The first shield portion 314 includes a central shield component 330, a first side shield component 328, and a second side shield component 332. The first side shield component 328 is located opposite the second side shield component 332, and the central shield component 330 is located between the first side shield component 328 and the second side shield component 332. The central shield component 330 may be configured to cover a central portion 225 of the exposed electrical connections 222. The first side shield component 328 may be configured to cover a first side portion 227 of the exposed electrical connections 222. The second side shield component 332 may be configured to cover a second side portion 229 of the exposed electrical connections 222. In some implementations, the central shield component 330, the first side shield component 328, and the second side shield component 332 form a unitary component. For example, the central shield component 330, the first side shield component 328, and the second side shield component 332 may be a single, continuous structure (e.g., the central shield component 330, the first side shield component 328, and the second side shield component 332 may be formed from a monolithic piece of material). In some implementations, another combination of the central shield component 330, the first side shield component 328, and the second side shield component 332 form a unitary component. For example, the central shield component 330 and the first side shield component 328 may form a unitary component. In another example, the central shield component 330 and the second side shield component 332 may form a unitary component.

The shield assembly 326 is also shown to include a second shield portion 334. The second shield portion 334 may be configured to cover the flexible electrical connector 224 to dissipate and/or redirect an electrical charge directed toward the flexible electrical connector 224. As shown, the second shield portion 334 may also be configured to cover a portion of the first surface 220 of the optical module control board 218.

In some implementations, the first shield portion 314 and the second shield portion 334 are formed from the same material. For example, the first shield portion 314 and the second shield portion 334 may be formed from metal (e.g., copper, aluminum, zinc, nickel, brass, steel, etc., or a combination thereof). Metals are generally good electrical conductors. Thus, any metal have suitable electrical conductivity may direct the electrical charge (e.g., from electrostatic discharge or electrostatic coupling) toward a ground component (e.g., the frame 104 of the head-mounted device 100) to direct the electrical charge away from electrical components (e.g., the optical module control board 218, the flexible electrical connector 224, etc.) of the head-mounted device 100. The first shield portion 314 and the second shield portion 334 may also be formed from plastic (e.g., polycarbonate, polypropylene, nylon, plastic-backed adhesive tape such as shielding tape, etc., or a combination thereof). In some implementations, the plastic may also include a conductive material (e.g., the plastic may be coated with a conductive material and/or the plastic may be blended with the conductive material to direct the electrical charge toward a ground components). The conductive material may be metal.

In an example, the first shield portion 314 and the second shield portion 334 may be formed from different materials. For example, the first shield portion 314 and the second shield portion 334 may both be formed from metal, but may be formed from different metals (e.g., the first shield portion 314 may be formed from aluminum and the second shield portion 334 may be formed from steel). As another example, the first shield portion 314 and the second shield portion 334 may both be formed from plastic, but may be formed from different plastics (e.g., the first shield portion 314 may be formed from polycarbonate and the second shield portion 334 may be formed from polypropylene). In another example, the first shield portion 314 may be formed from metal and the second shield portion 334 may be formed from plastic. The first shield portion 314 may also be formed from plastic and the second shield portion 334 may be formed from metal.

In some implementations, the first shield portion 314 and the second shield portion 334 are flexible (e.g., the first shield portion 314 may be configured to conform to a shape of a surface covered by the first shield portion 314 and the second shield portion 334 may be configured to conform to a shape of a surface covered by the second shield portion 334). The first shield portion 314 may also be rigid (e.g., the first shield portion 314 may be configured to not conform to a shape of a surface covered by the first shield portion 314), and the second shield portion 334 may be flexible. In some implementations, the first shield portion 314 may be flexible and the second shield portion 334 may be rigid.

In an example, the shield assembly 326 includes an adhesive configured to couple the shield assembly 326 to the optical module control board 218 and the flexible electrical connector 224. More specifically, the shield assembly 326 may be a shielding tape. For example, the first shield portion 314 may include a first adhesive (e.g., rubber adhesive, acrylic adhesive, silicone adhesive, etc.) configured to couple the first shield portion 314 to the first surface 220. Thus, the first shield portion 314 may be configured to couple with the first surface 220 of the optical module control board 218 using the first adhesive. The second shield portion 334 may include a second adhesive configured to couple the second shield portion 334 to the flexible electrical connector 224. Accordingly, the second shield portion 334 may be configured to couple with the flexible electrical connector 224 using the second adhesive. In some implementations, the first adhesive and the second adhesive are the same. The first adhesive and the second adhesive may also be different.

Additionally, though the shield assembly 326 was described above as covering the first surface 220, the shield assembly 326 may also be configured to cover the first surface 220, the second surface 338, the edge 336, or a combination thereof. Accordingly, the shield assembly 326 may extend from the first surface 220, around the edge 336, to cover a portion of the second surface 338.

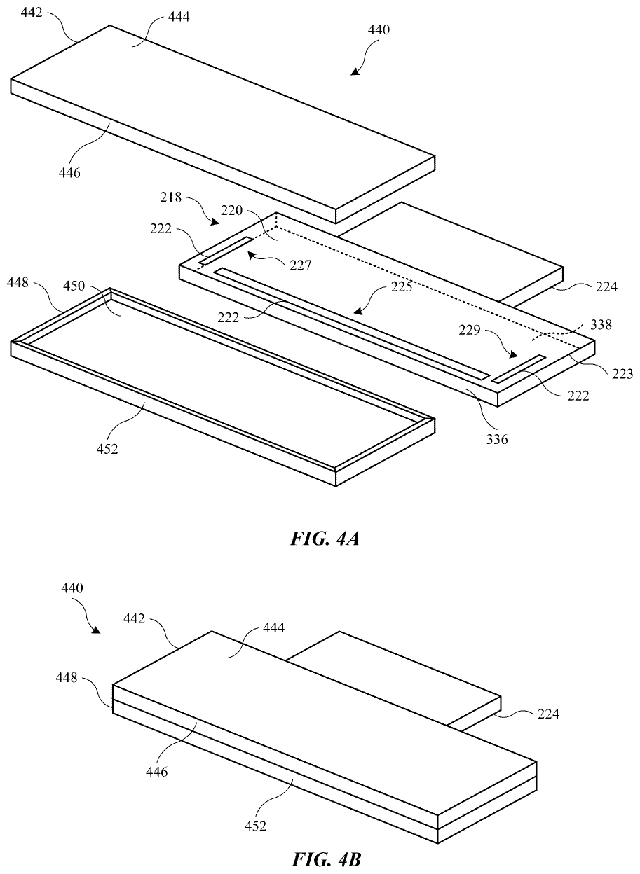

FIGS. 4A-4B are illustrations of a shield assembly 440. FIG. 4A is an illustration of an exploded view of the shield assembly 440. FIG. 4B is an illustration of the shield assembly 440 in an assembled configuration and coupled to the optical module control board 218. The shield assembly 440 may be configured to cover a portion of the optical module control board 218 (and the exposed electrical connections 222) to dissipate and/or redirect an electrical charge that is directed toward the exposed electrical connections 222. For example, the shield assembly 440 may be physically coupled to the optical module control board 218 such that at least a portion of the shield assembly 440 is spaced from the first surface 220, and such that the electrical connections 222 are located between the first surface 220 and the shield assembly 326.

The shield assembly 440 includes a first shield portion 442. The first shield portion 442 is sized to receive the first surface 220 and a portion of the edge 336. The first shield portion 442 may be formed as a monolithic structure. For example, the first shield portion 442 may be formed from plastic by an injection molding or machining process (e.g., the first shield portion 442 may be formed from a monolithic piece of material). An outer surface 444 of the first shield portion 442 may be configured to cover the first surface 220. More specifically, the outer surface 444 may be configured to cover the central portion 225 of the exposed electrical connections 222, the first side portion 227 of the exposed electrical connections 222, and the second side portion 229 of the exposed electrical connections 222. An edge surface 446 of the first shield portion 442 may be configured to cover a portion of the edge 336.

The shield assembly 440 also includes a second shield portion 448. The second shield portion 448 is sized to receive the second surface 338 and a portion of the edge 336. The second shield portion 448 may be a monolithic structure similar to the first shield portion 442 (e.g., the second shield portion 448 may be formed from a monolithic piece of material via an injection molding or machining process). In some implementations, the first shield portion 442 and the second shield portion 448 are identical. An outer surface 450 of the second shield portion 448 may be configured to cover the second surface 338. An edge surface 452 may be configured to cover a portion of the edge 336. The first shield portion 442 and the second shield portion 448 may also include complementary surfaces configured to engage with each other to cover the optical module control board 218. For example, the first shield portion 442 may have protrusions along the edge surface 446 that extend toward the second shield portion 448. The edge surface 452 of the second shield portion 448 may define recesses configured to receive the protrusions such that the first shield portion 442 and the second shield portion 448 may engage each other based on engagement between the respective protrusions and recesses.

In some implementations, the shield assembly 440 may be configured to cover the optical module control board 218 and the flexible electrical connector 224. In an example, the first shield portion 442 may be sized to receive both the optical module control board 218 and the flexible electrical connector 224, and the second shield portion 448 may be sized to receive both the optical module control board 218 and the flexible electrical connector 224. In some implementations, the first shield portion 442 may include multiple components (e.g., one component that covers the first surface 220 of the optical module control board 218 and another component that covers the flexible electrical connector 224). The second shield portion 448 may also include multiple components (e.g., one component that covers the second surface 338 of the optical module control board 218 and another component that covers the flexible electrical connector 224).

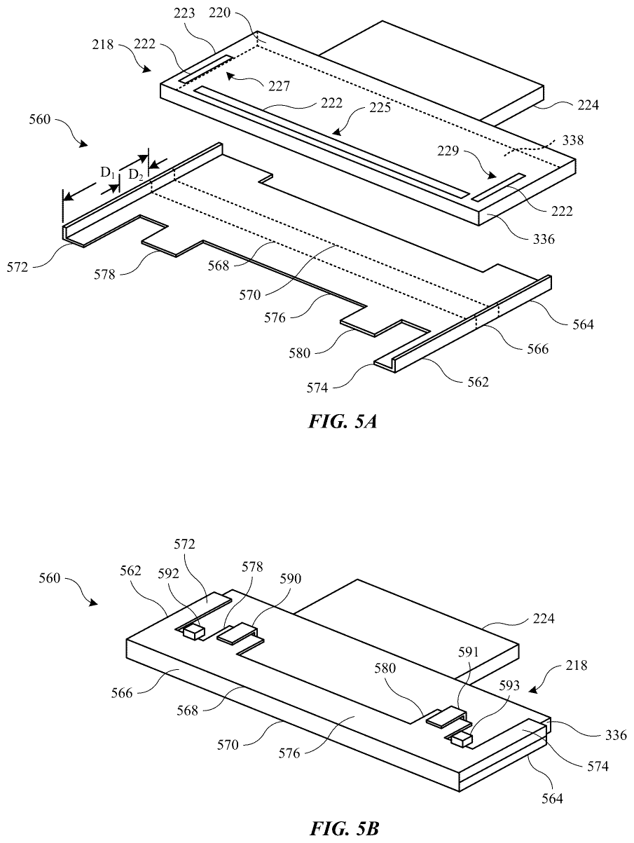

FIGS. 5A-5B are illustrations of a deformable shield 560. FIG. 5A is an illustration of the deformable shield 560 in an unformed state. FIG. 5B is an illustration of the deformable shield 560 in a formed state and coupled with the optical module control board 218.

The deformable shield 560 may be configured to cover the optical module control board 218 to dissipate and/or redirect an electrical charge. For example, the deformable shield 560 may be physically coupled to the optical module control board 218 such that at least a portion of the deformable shield 560 is spaced from the first surface 220, and such that the electrical connections 222 are located between the first surface 220 and the deformable shield 560.

In some implementations, the deformable shield 560 is formed from an electrically conductive material configured to direct the electrical charge away from the optical module control board 218. For example, the deformable shield 560 may be formed from metal, and the metal may direct the electrical charge to a ground surface to dissipate and/or redirect the electrical charge. In some implementations, the deformable shield 560 is formed from a monolithic piece of thin-walled metal (e.g., the deformable shield 560 may be a unitary component). For example, the thin-walled metal may have a wall thickness of between 0.1 millimeters (mm) and 2 mm. In some implementations, the thin-walled metal may have a wall thickness of between 0.2 mm and 1.5 mm. The thin-walled metal may also have a wall thickness of between 0.3 mm and 1 mm. Being formed from a monolithic piece of thin-walled metal allows the deformable shield 560 to be formed (e.g., to undergo a change from the unformed state to the formed state) by sheet metal manufacturing processes such as stamping, drawing, bending, etc. The deformable shield 560 may also include the thin-walled metal in the form of a metal mesh configured to act as a Faraday cage. For example, the thin-walled metal may neutralize an external electrical field (e.g., an electrical charge from an electrostatic discharge or electrostatic coupling) such that the optical module control board and/or the flexible electrical connector 224 are shielded from the electrical charge.

During the forming process, the deformable shield 560 may be bent along a first bending axis 568 and a second bending axis 570 to create different portions of the deformable shield 560. In the example shown, the deformable shield 560 is shown to include a first shield portion 562, a second shield portion 564, and a third shield portion 566. In the formed state, the first shield portion 562 may be configured to cover the first surface 220 to direct the electrical charge away from the first surface 220. More specifically, the first shield portion 562 may be configured to cover the exposed electrical connections 222 on the first surface 220 to direct the electrical charge away from the exposed electrical connections 222. The second shield portion 564 may be configured to cover the second surface 338 to direct the electrical charge away from the second surface 338. The third shield portion 566 may be configured to cover the edge 336 to direct the electrical charge away from the edge 336.

In some implementations, the deformable shield 560 may be configured to limit gaps between the first shield portion 562 and the third shield portion 566, and between the second shield portion 564 and the third shield portion 566. Limiting gaps may limit the ability of an electrical charge to accumulate on the optical module control board 218 through the gaps. For example, the thin-walled metal of the deformable shield 560 may yield (e.g., stretch, elongate, etc.) along the first bending axis 568 during the forming process while limiting gap formation along or near the first bending axis 568. The thin-walled metal of the deformable shield 560 may also yield along the second bending axis 570 during the forming process while limiting gap formation along or near the second bending axis 570.

In some implementations, the first shield portion 562 has a first arm 572 located opposite a second arm 574. A central arm 576 is located between the first arm 572 and the second arm 574. The central arm 576 may be configured to cover the central portion 225 of the exposed electrical connections 222 located on the first surface 220. The first arm 572 may be configured to cover the first side portion 227 of the exposed electrical connections 222 located on the first surface 220. The second arm 574 may be configured to cover the second side portion 229 of the exposed electrical connections 222 located on the first surface 220. In some implementations, the first arm 572 and the second arm 574 are configured to extend a first distance D₁ from the first bending axis 568. The central arm 576 may be configured to extend a second distance D₂ from the first bending axis 568. In some implementations, D₁ is greater than D₂ (e.g., the first arm 572 and the second arm 574 extend further from the first bending axis 568 than the central arm 576). D₂ may also be greater than D₁ (e.g., the central arm 576 extends further from the first bending axis 568 than the first arm 572 and the second arm 574).

The deformable shield 560 also includes a first tab 578 coupled to and extending from the central arm 576 in a direction away from the first bending axis 568. The deformable shield 560 is also shown to include a second tab 580 coupled to and extend from the central arm 576 in a direction away from the first bending axis 568. The first tab 578 and the second tab 580 are configured to facilitate coupling the deformable shield 560 to the optical module control board 218. For example, as shown in FIG. 5B, the optical module control board 218 may include a first arm 590 configured to engage the first tab 578. The optical module control board 218 may also include a second arm 591 configured to engage the second tab 580. In some implementations, the first arm 590 and the second arm 591 may be biased toward the first surface 220 such that the deformable shield 560 is secured to the optical module control board 218 by the first arm 590 and the second arm 591.

In some implementations, the deformable shield 560 may be secured to the optical module control board 218 with a fastener. For example, as shown in FIG. 5B, the deformable shield 560 may be secured to the optical module control board 218 using a first fastener 592 and/or a second fastener 593. The first fastener 592 and the second fastener 593 may by any type of fastener suitable to secure the deformable shield 560 to the optical module control board 218. For example, the first fastener 592 and the second fastener 593 may be threaded fasteners (e.g., screws, bolts, etc.) or nonthreaded fasteners (e.g., rivets, pins, clamps, etc.). In some implementations, the first fastener 592 and the second fastener 593 may be the same type of fastener. The first fastener 592 and the second fastener 593 may also be different types of fasteners.

In some implementations, the deformable shield 560 may be secured to the optical module control board 218 using the tabs (e.g., the first tab 578 and the second tab 580) and the fasteners (e.g., the first fastener 592 and the second fastener 593). The deformable shield 560 may also be secured to the optical module control board 218 using the tabs or the fasteners.

The deformable shield 560 may also include a fourth shield portion, in some implementations. The fourth shield portion may be configured to cover the flexible electrical connector 224 to direct the electrical charge away from the flexible electrical connector 224. The fourth shield portion may be similar in structure and materials to the second shield portion 334 of FIGS. 3A-3B. In some implementations, the fourth shield portion is coupled to and extends from the first shield portion 562 (e.g., the first shield portion 562, the second shield portion 564, the third shield portion 566, and the fourth shield portion form a monolithic structure). The fourth shield portion may also be separate from the first shield portion 562.

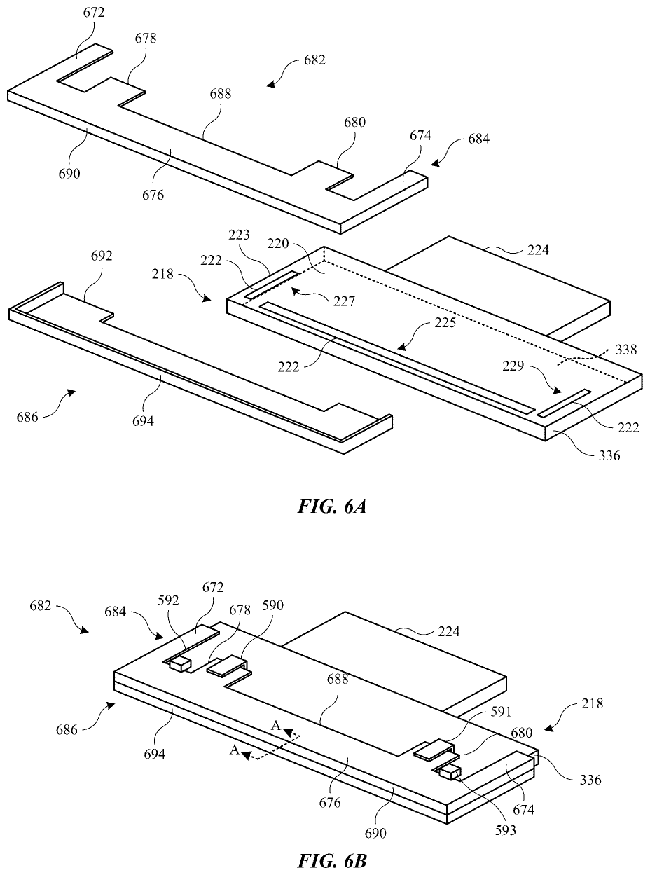

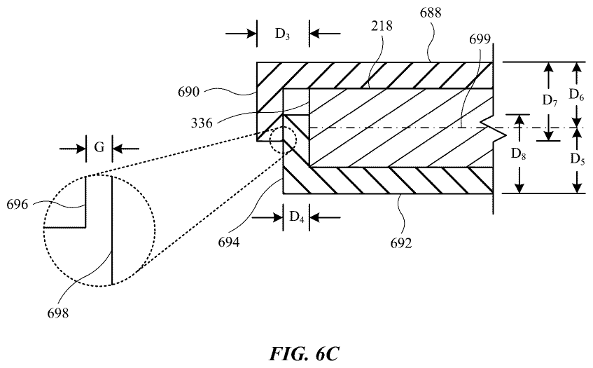

FIGS. 6A-6C are illustrations of a shield assembly 682. FIG. 6A is an illustration of an exploded view of the shield assembly 682. FIG. 6B is an illustration of the shield assembly 682 in an assembled configuration and coupled to the optical module control board 218. FIG. 6C is an illustration of a cross-section of the shield assembly 682 taken across line A-A of FIG. 6B.

The shield assembly 682 may be configured to cover the optical module control board 218 to dissipate and/or redirect an electrical charge that would otherwise be directed toward the shield assembly 682. For example, the shield assembly 682 may be physically coupled to the optical module control board 218 such that at least a portion of the shield assembly 682 is spaced from the first surface 220, and such that the electrical connections 222 are located between the first surface 220 and the shield assembly 682.

The shield assembly 682 includes a first shield portion 684 configured to cover a portion of the optical module control board 218. For example, the first shield portion 684 is shown to include a first shield outer section 688 configured to cover the first surface 220 to cover the exposed electrical connections 222 (e.g., to direct the electrical charge away from the electrical connections 222). The first shield portion 684 also includes a first shield edge section 690 configured to cover a first portion of the edge 336 to direct the electrical charge away from the edge 336. As shown, the first shield outer section 688 and the first shield edge section 690 are oriented along different planes. For example, the first shield outer section 688 may be oriented along a plane parallel to the first surface 220. The first shield edge section 690 may be oriented along a plane parallel to the edge 336. In some implementations, the first shield outer section 688 and the first shield edge section 690 are oriented along different planes that are perpendicular to each other (e.g., if the first surface 220 and the edge 336 are perpendicular to each other, then the first outer shield section 688 and the first side shield edge section 690 may be perpendicular to each other). The first shield outer section 688 and the first shield edge section 690 may also be oriented along different planes that are oblique to each other (e.g., if the first surface 220 and the edge 336 are not perpendicular to each other, then the first outer shield section 688 and the first side shield edge section 690 may not be perpendicular to each other).

The first shield portion 684 may also include a first tab 678 and a second tab 680. The first tab 678 and the second tab 680 are similar in structure and function to the first tab 578 and the second tab 580 of FIGS. 5A-5B. Thus, the first tab 678 and the second tab 680 may be used to secure the first shield portion 684 to the optical module control board 218. The first shield portion 684 may also be secured to the optical module control board 218 using the first fastener 592 and/or the second fastener 593 as described with reference to FIGS. 5A-5B.

In some implementations, the first shield portion 684 has a first arm 672 located opposite a second arm 674. A central arm 676 is located between the first arm 572 and the second arm 574. The first arm 672, the second arm 674, and the central arm 676 have a structure and function similar to that of the first arm 572, the second arm 574, and the central arm 576 of FIGS. 5A-5B. For example, the central arm 676 may be configured to cover the central portion 225 of the exposed electrical connections 222, the first arm 572 may be configured to cover the first side portion 227 of the exposed electrical connections 222, and the second arm 574 may be configured to cover the second side portion 229 of the exposed electrical connections 222.

The shield assembly 682 also includes a second shield portion 686 configured to cover a portion of the optical module control board 218. For example, the second shield portion 686 is shown to include a second shield outer section 692 configured to cover the second surface 338 to direct the electrical charge away from the second surface 338. The second shield portion 686 is also shown to include a second shield edge section 694 configured to cover a second portion of the edge 336 to direct the electrical charge away from the edge 336. In some implementations, the second shield outer section 692 and the second shield edge section 694 are oriented along different planes. For example, the second shield outer section 692 may be oriented along a plane parallel to the second surface 338. The second shield edge section 694 may be oriented along a plane parallel to the edge 336. In some implementations, the second shield outer section 692 and the second shield edge section 694 may be oriented along different planes that are perpendicular to each other (e.g., if the second surface 338 and the edge 336 are perpendicular to each other, then the second outer shield section 692 and the second side shield edge section 694 may be perpendicular to each other). The second shield outer section 692 and the second shield edge section 694 may also be oriented along different planes that are oblique to each other (e.g., if the second surface 338 and the edge 336 are not perpendicular to each other, then the second outer shield section 692 and the second side shield edge section 694 may not be perpendicular to each other). The second shield portion 686 may be secured to the optical module control board 218 in a manner similar to that of the first shield portion 684. For example, the first fastener 592 and/or the second fastener 593 may be used to secure the second shield portion 686 to the optical module control board 218.

The first shield portion 684 and the second shield portion 686 (e.g., the shield assembly 682) may be formed from electrically conductive materials configured to dissipate and/or redirect the electrical charge (e.g., to direct the electrical charge away from the optical module control board 218). For example, the first shield portion 684 and the second shield portion 686 may be formed from metal. The metal may direct the electrical charge to a ground surface to dissipate and/or redirect the electrical charge.

In some implementations, the first shield edge section 690 overlaps the second shield edge section 694 across a longitudinal axis 699 of the optical module control board 218. For example, as shown in FIG. 6C, the first shield edge section 690 may extend outward beyond the edge 336 further than the second shield edge section 694. More specifically, the first shield edge section 690 may extend beyond the edge 336 by a distance D₃. The second shield edge section 694 may extend beyond the edge 336 by a distance D₄, and D₃ may be greater than D₄ such that the first shield edge section 690 extends beyond the second shield edge section 694.

Additionally, the longitudinal axis 699 is positioned such that a distance D₅ from the second shield outer section 692 to the longitudinal axis 699 is approximately equal (e.g., within 1 mm of being equal) to a distance D₆ from the first shield outer section 688 to the longitudinal axis 699. In some implementations, the first shield edge section 690 extends a distance D₇ toward the longitudinal axis 699, and D₇ may be greater than D₆. The second shield edge section 694 may extend a distance D₈ toward the longitudinal axis 699, and D₈ may be greater than D₅. Thus, the first shield edge section 690 overlaps the second shield edge section 694 by a distance of (D₇+D₈)−(D₅+D₆).

In some implementations, a first complementary surface 696 of the first shield edge section 690 contacts a second complementary surface 698 of the second shield edge section 694 when the first shield edge section 690 overlaps the second shield edge section 694. Thus, there may be no gap between the first complementary surface 696 and the second complementary surface 698. In the example shown in FIG. 6C, the first complementary surface 696 extends beyond the second complementary surface 698 such that there is a gap G between the first complementary surface 696 and the second complementary surface 698. In some implementations, the gap G between the first complementary surface 696 and the second complementary surface 698 is less than 2 mm. The gap G between the first complementary surface 696 and the second complementary surface 698 may also be less than 1 mm.

In some implementations, the overlap between the first shield edge section 690 and the second shield edge section 694 may be configured such that the first shield edge section 690 may be configured to direct liquid away from the optical module control board 218. For example, the first shield edge section 690 may be oriented higher than the second shield edge section 694 in a vertical direction. Thus, if liquid is introduced into the head-mounted device 100, the first shield edge section 690 may direct the liquid away from the optical module control board 218. Directing the liquid away from the optical module control board 218 may prevent performance issues that may arise from liquid infiltrating the optical module control board 218.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create three-dimensional or spatial audio environment that provides the perception of point audio sources in three-dimensional space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationary with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer-generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mounted systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mounted system may have one or more speaker(s) and an integrated opaque display. Alternatively, a head-mounted system may be configured to accept an external opaque display (e.g., a smartphone). The head-mounted system may incorporate one or more imaging sensors to capture images or video of the physical environment, and/or one or more microphones to capture audio of the physical environment. Rather than an opaque display, a head-mounted system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

As described above, one aspect of the present technology is the gathering and use of data available from various sources for use during operation of a head-mounted device. As an example, such data may identify the user and include user-specific settings or preferences. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, a user profile may be established that stores user related information that allows adjustment of one or more optical modules of the head-mounted device according to user preferences. Accordingly, use of such personal information data enhances the user's experience.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of storing a user profile for adjustment of an optical module, the present technology can be configured to allow users to select to “opt in” or “opt out” of participation in the collection of personal information data during registration for services or anytime thereafter. In another example, users can select not to provide data regarding usage of specific applications. In yet another example, users can select to limit the length of time that application usage data is maintained or entirely prohibit the development of an application usage profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, user information may be determined each time the head-mounted device is used, such as by obtaining the user information in real time, and without subsequently storing the information or associating with the particular user.

What is claimed is:

1. A head-mounted device, comprising:
a frame;
a stage movably coupled to the frame;
an optical module coupled to the stage and configured to move laterally relative to the frame, the optical module configured to show content;
an optical module control board configured to provide the content to the optical module and having a surface that includes exposed electrical connections positioned around a perimeter of the surface;
a flexible electrical connector electrically coupled to the optical module and to the optical module control board; and
a shield assembly, comprising:
a first shield portion configured to cover the surface of the optical module control board, to extend partially around the perimeter of the surface to cover the exposed electrical connections, and to dissipate an electrical charge, and
a second shield portion configured to cover the flexible electrical connector to dissipate the electrical charge.

2. The head-mounted device of claim 1, wherein the first shield portion includes a central shield component configured to cover a central portion of the exposed electrical connections, a first side shield component configured to cover a first side portion of the exposed electrical connections, and a second side shield component configured to cover a second side portion of the exposed electrical connections.

3. The head-mounted device of claim 2, wherein the central shield component, the first side shield component, and the second side shield component form a unitary component.

4. The head-mounted device of claim 1, wherein the first shield portion and the second shield portion are flexible.

5. The head-mounted device of claim 1, wherein the first shield portion is rigid and the second shield portion is flexible.

6. The head-mounted device of claim 1, wherein the first shield portion includes a first adhesive, wherein the first shield portion is configured to couple with the surface of the optical module control board using the first adhesive, wherein the second shield portion includes a second adhesive, and wherein the second shield portion is configured to couple with the flexible electrical connector using the second adhesive.

7. A head-mounted device, comprising:
a frame;
an optical module coupled to the frame and configured to show content;
an optical module control board configured to provide the content to the optical module and having a first surface having exposed electrical connections positioned around a perimeter of the first surface, a second surface located opposite the first surface, and an edge extending between the first surface and the second surface; and
a deformable shield configured to cover the optical module control board, comprising:
a first shield portion configured to cover the first surface to direct an electrical charge away from the first surface,
a second shield portion configured to cover the second surface to direct the electrical charge away from the second surface, and
a third shield portion configured to cover the edge to direct the electrical charge away from the edge.

8. The head-mounted device of claim 7, wherein the deformable shield is configured to limit gaps between the first shield portion and the third shield portion, and between the second shield portion and the third shield portion.

9. The head-mounted device of claim 7, wherein the first shield portion is configured to cover the exposed electrical connections.

10. The head-mounted device of claim 7, wherein the deformable shield is formed from metal.

11. The head-mounted device of claim 10, wherein the deformable shield is formed from a monolithic piece of thin-walled metal.

12. The head-mounted device of claim 11, wherein the thin-walled metal has a wall thickness of between 0.3 millimeters and 1 millimeter.

13. The head-mounted device of claim 11, further comprising a flexible electrical connector coupled to the optical module control board and to the optical module, wherein a fourth shield portion is configured to cover the flexible electrical connector to direct the electrical charge away from the flexible electrical connector.

14. A head-mounted device, comprising:
a frame;
an optical module movable relative to the frame and configured to show content;
an optical module control board configured to provide the content to the optical module and having a first surface that includes exposed electrical connections positioned around a perimeter of the first surface, a second surface located opposite the first surface, and an edge extending between the first surface and the second surface; and
a shield assembly, comprising:
a first shield portion having a first shield outer section configured to cover the first surface and a first shield edge section configured to cover a first portion of the edge, wherein the first shield outer section and the first shield edge section are oriented along different planes, and
a second shield portion having a second shield outer section configured to cover the second surface and a second shield edge section configured to cover a second portion of the edge, wherein the second shield outer section and the second shield edge section are oriented along different planes.

15. The head-mounted device of claim 14, wherein the first shield portion and the second shield portion are formed from metal.

16. The head-mounted device of claim 14, wherein the first shield edge section overlaps the second shield edge section.

17. The head-mounted device of claim 16, wherein a first complementary surface of the first shield edge section contacts a second complementary surface of the second shield edge section.

18. The head-mounted device of claim 14, wherein the first shield edge section extends beyond the edge of the optical module control board further than the second shield edge section.

19. The head-mounted device of claim 18, wherein a gap between a first complementary surface of the first shield edge section and a second complementary surface of the second shield edge section is less than 1 millimeter.

20. The head-mounted device of claim 18, wherein the first shield edge section is configured to direct liquid away from the optical module control board.
